(19) United States
(12) Patent Application Publication
(10) Pub. No.: US 2026/0233380 A1
(43) Pub. Date: Aug. 13, 2026

(54) MAINTENANCE SYSTEM AND MAINTENANCE METHOD

(71) Applicant: Tokyo Electron Limited, Tokyo (JP)

(72) Inventors: Gaku IKEDA, Tokyo (JP); Shinsuke TAKAKI, Kumamoto (JP); Takuya MORI, Tokyo (JP)

(73) Assignee: Tokyo Electron Limited, Tokyo (JP)

(21) Appl. No.: 19/531,718

(22) Filed: Feb. 6, 2026

(30) Foreign Application Priority Data
Feb. 13, 2025 (JP) 2025-021429
Jan. 14, 2026 (JP) 2026-004551

(51) Int. Cl. B25J 9/04; B25J 9/02; B25J 9/16; B66F 3/24

(52) U.S. Cl. CPC B25J 9/042; B25J 9/023; B25J 9/1689; B66F 3/24

(57) ABSTRACT

A maintenance system includes a rail, a working robot, and a self-propelled carriage. The rail is fixed on an outer side part of a substrate processing apparatus that has a processing unit, and extends in a vertical direction. The working robot is capable of being attached to or detached from the rail and is capable of being lifted or lowered along the rail. The self-propelled carriage transfers the working robot. The working robot includes an arm that is capable of going to an inside of the processing unit.

### CROSS-REFERENCE TO RELATED APPLICATION(S)

This application is based upon and claims the benefit of priority to Japanese Patent Application No. 2025-021429, filed on Feb. 13, 2025, the entire contents of which are herein incorporated by reference, and Japanese Patent Application No. 2026-004551, filed on Jan. 14, 2026, the entire contents of which are herein incorporated by reference.

### FIELD

A disclosed embodiment relates to a maintenance system and a maintenance method.

### BACKGROUND

Japanese Patent Application Publication No. 2022-083851 discloses a substrate processing apparatus that has a plurality of laminated processing blocks. Each processing block has a plurality of processing modules that are provided so as to be laminated on one another.

For an apparatus for automating maintenance of a substrate processing apparatus, it is possible to consider, for example, a maintenance apparatus that includes a robot, a lifting/lowering shaft where such a robot is lifted/lowered thereon, and a moving mechanism that moves such a robot and such a lifting/lowering shaft to such a substrate processing apparatus.

However, in such a maintenance apparatus, a position of a center of gravity of such a maintenance apparatus is high when maintenance thereof is executed at a comparatively high position in a vertical direction, so that a robot may readily be wobbled so as to degrade a working accuracy of such a robot.

A problem as described above may be caused in not only a substrate processing apparatus with a plurality of laminated processing blocks (processing modules) but also a general substrate processing apparatus. For example, in a substrate processing apparatus that has a processing module with a comparatively large dimension in a vertical direction, a problem as described above may be caused even if such a processing module is configured to be a single stage. Furthermore, a problem as described above may also be caused in a case where a processing module is laminated on a component other than such a processing module, for example, a component such as an exhaust system or a power supply system.

### SUMMARY

A maintenance system according to an embodiment includes a rail that is fixed on an outer side part of a substrate processing apparatus that includes a processing unit, and that extends in a vertical direction, a working robot that is capable of being attached to or detached from the rail and that is capable of being lifted or lowered along the rail, and a self-propelled carriage that transfers the working robot, wherein the working robot includes an arm that is capable of going to an inside of the processing unit.

### BRIEF DESCRIPTION OF DRAWING(S)

FIG. 1 is a plan view that illustrates an example of a configuration of a substrate processing apparatus and a maintenance system according to a first embodiment.

FIG. 2 is a perspective view that illustrates an example of a configuration of a maintenance system according to a first embodiment.

FIG. 3 is a side view that illustrates a situation of maintenance that is executed by a maintenance system according to a first embodiment.

FIG. 4 is a plan view that illustrates an example of a configuration of a substrate processing apparatus and a maintenance system according to a second embodiment.

FIG. 5 is a side view that illustrates a situation of maintenance that is executed by a maintenance system according to a second embodiment.

FIG. 6 is a side view that illustrates a situation of maintenance that is executed by a maintenance system according to a third embodiment.

FIG. 7 is a plan view for explaining an operation of a maintenance system according to a fourth embodiment.

FIG. 8 is a side view for explaining an operation of a maintenance system according to a fourth embodiment.

FIG. 9 is a plan view for explaining an operation of a maintenance system according to a fifth embodiment.

FIG. 10 is a side view for explaining an operation of a maintenance system according to a fifth embodiment.

### DESCRIPTION OF EMBODIMENT(S)

Hereinafter, a mode(s) (that will be described as “an embodiment(s)” below) for implementing a maintenance system and a maintenance method according to the present disclosure will be explained in detail with reference to the drawing(s). Additionally, the present disclosure is not limited by such an embodiment(s). Furthermore, it is possible to combine respective embodiments appropriately as long as processing contents thereof are not inconsistent. Furthermore, in respective embodiments as provided below, an identical site will be provided with an identical sign so as to omit a redundant explanation(s) thereof.

Furthermore, in an embodiment(s) as illustrated below, an expression of “orthogonal” or “parallel” may be used where such an expression does not need being strictly “orthogonal” or “parallel”. That is, each expression as described above allows, for example, a deviation of an accuracy of manufacturing, an accuracy of installation, etc.

### First Embodiment

### Configuration of Substrate Processing Apparatus

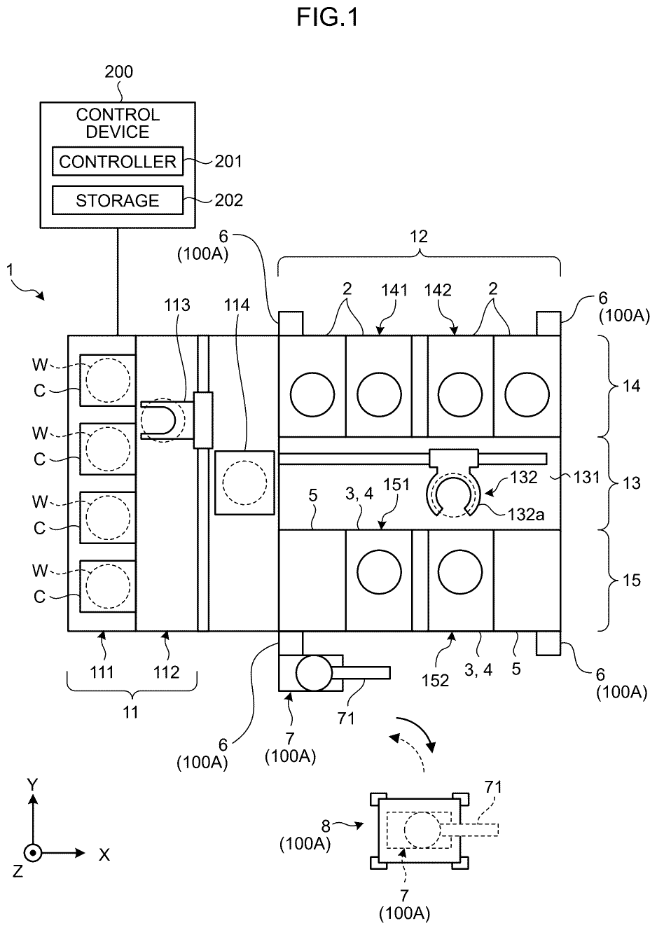

First, a configuration of a substrate processing apparatus 1 according to a first embodiment will be explained with reference to FIG. 1. FIG. 1 is a plan view that illustrates an example of a configuration of a substrate processing apparatus 1 and a maintenance system 100A according to a first embodiment.

As illustrated in FIG. 1, a substrate processing apparatus 1 includes a carrying-in/out station 11 and a processing station 12. The carrying-in/out station 11 and the processing station 12 are provided adjacently.

The carrying-in/out station 11 includes a carrier placing section 111 and a transfer section 112. A plurality of carriers C that house a plurality of semiconductor wafers W (that will be described as “wafers W” below) in a horizontal state thereof are placed in the carrier placing section 111.

The transfer section 112 is provided so as to be adjacent to the carrier placing section 111. A transfer device 113 and a delivery unit 114 are arranged in an inside of the transfer section 112.

The transfer device 113 includes a wafer holding mechanism that holds a wafer W. Furthermore, the transfer device 113 is capable of moving in a horizontal direction and a vertical direction and turning around a vertical axis as a center thereof, and executes transfer of a wafer W between a carrier C and the delivery unit 114 by using a wafer holding mechanism.

The delivery unit 114 temporarily places a wafer W thereon.

The processing station 12 is provided so as to be adjacent to the transfer section 112. The processing station 12 includes a transfer block 13, a first processing block 14, and a second processing block 15.

The transfer block 13 includes a transfer area 131 and a transfer device 132. The transfer area 131 is, for example, an area with a rectangular solid shape that extends along a direction of arrangement of the carrying-in/out station 11 and the processing station 12 (a direction of an X-axis). The transfer device 132 is arranged in the transfer area 131.

The transfer device 132 includes a wafer holding mechanism 132a that holds a wafer W. Furthermore, the transfer device 132 is capable of moving in a horizontal direction and a vertical direction and turning around a vertical axis as a center thereof, and executes transfer of a wafer W among the delivery unit 114, the first processing block 14, and the second processing block 15 by using the wafer holding mechanism 132a.

The first processing block 14 and the second processing block 15 are arranged so as to be adjacent to the transfer area 131 on both sides of the transfer area 131. As an example, the first processing block 14 is arranged on one side of the transfer area 131 (a side of a positive direction of a Y-axis) in a direction (a direction of a Y-axis) that is orthogonal to a direction of arrangement of the carrying-in/out station 11 and the processing station 12 (a direction of an X-axis). Furthermore, the second processing block 15 is arranged on another side of the transfer area 131 (a side of a negative direction of a Y-axis) in a direction (a direction of a Y-axis) that is orthogonal to a direction of arrangement of the carrying-in/out station 11 and the processing station 12 (a direction of an X-axis).

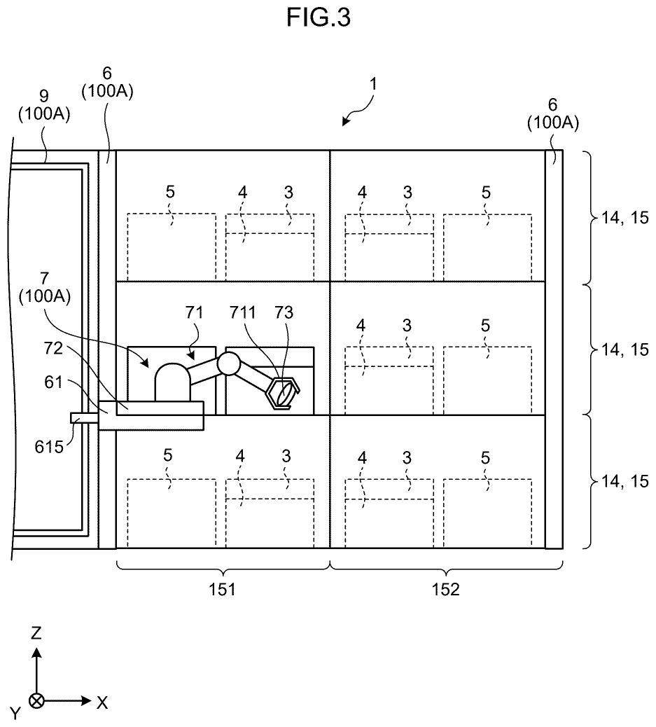

The first processing block 14 and the second processing block 15 may be arranged in multiple stages along a vertical direction (see FIG. 3). For example, in the substrate processing apparatus 1 according to a first embodiment, each of the first processing block 14 and the second processing block 15 is arranged in three stages. Additionally, a number of a stage(s) of such a plurality of processing blocks is not particularly limited.

Transfer of a wafer W between the first processing block 14 and the second processing block 15, and the delivery unit 114 may be executed by a single transfer device 132 that is arranged in the transfer block 13.

The first processing block 14 may have a first area 141 and a second area 142 along a direction of an X-axis. Furthermore, the second processing block 15 may have a third area 151 and a fourth area 152 along a direction of an X-axis.

A plurality of (herein, two) liquid processing units 2 (an example of a processing unit(s)) may be arranged in each of the first area 141 and the second area 142. As illustrated in FIG. 1, the plurality of liquid processing units 2 are arranged side by side, for example, along a direction of an X-axis.

A measurement unit 3 (an example of a processing unit), a drying unit 4 (an example of a processing unit), and a supply unit 5 may be arranged in each of the third area 151 and the fourth area 152. The measurement unit 3 may be arranged on an upper part of the drying unit 4 (see FIG. 3). The measurement unit 3 and the drying unit 4, and the supply unit 5 may be arranged side by side along a direction of an X-axis.

Such a liquid processing unit 2 executes a cleaning process that cleans an upper surface of a wafer W that is a pattern formation surface thereof. Furthermore, the liquid processing unit 2 executes a liquid film formation process that supplies a liquid of IPA (isopropyl alcohol) to an upper surface of a wafer W after a cleaning process so as to form a liquid film thereof.

The measurement unit 3 may measure, for example, weights of a wafer W before and after a liquid film formation process. Then, a controller 201 as described later may calculate, for example, an amount of a liquid film that is formed on an upper surface of a wafer W, by a liquid film formation process, from weights of such a wafer W before and after such a liquid film formation process that are measured by the measurement unit 3.

The drying unit 4 executes a drying process for a wafer W after a liquid film formation process. Specifically, the drying unit 4 causes a wafer W after a liquid film formation process to contact a processing fluid in a supercritical state thereof so as to dry such a wafer W. According to such a drying process, it is possible to dry a wafer W while collapse of a pattern that is formed on an upper surface of such a wafer W is reduced or prevented.

The supply unit 5 supplies a processing fluid to the drying unit 4. Such a processing fluid may be, for example, CO₂. The supply unit 5 may include a supply instrument group that includes a flowmeter, a flow rate controller, a back pressure valve, a heater, etc., and a housing that houses such a supply instrument group.

Additionally, a processing unit(s) that is/are included in the substrate processing apparatus 1 is/are not limited to the liquid processing unit 2, the measurement unit 3, and the drying unit 4. The substrate processing apparatus 1 may include another processing unit that execute substrate processing for a wafer W. Additionally, in an explanation(s) as provided below, the liquid processing unit 2, the measurement unit 3, and the drying unit 4 may not particularly be distinguished and simply be described and explained as “a processing unit(s)”.

The substrate processing apparatus 1 includes a control device 200. The control device 200 is, for example, a computer, and includes a controller 201 and a storage 202.

The controller 201 includes a microcomputer that has a CPU (Central Processing Unit), a ROM (Read Only Memory), a RAM (Random Access Memory), an input/output port, etc., and/or various types of circuits. A CPU of such a microcomputer reads and executes a program that is stored in a ROM so as to realize control of the transfer devices 113, 132, the liquid processing unit 2, the drying unit 4, the supply unit 5, and a working robot 7 as described later, etc.

Additionally, such a program may have been recorded in a computer-readable recording medium and be installed in the storage 202 of the control device 200 from such a recording medium. For a computer-readable recording medium, for example, a hard disk (HD), a flexible disk (FD), a compact disk (CD), a magneto-optical disk (MO), a memory card, etc., are provided.

The storage 202 is realized by, for example, a semiconductor memory element such as a RAM or a flash memory, or a storage device such as a hard disk or an optical disk.

### Configuration of Maintenance System

Next, a configuration of a maintenance system 100A according to a first embodiment will be explained with reference to FIG. 1. As illustrated in FIG. 1, a maintenance system 100A executes maintenance of a substate processing apparatus 1. The maintenance system 100A has a rail 6, a working robot 7, and a carriage 8.

The rail 6 has a shape that extends in a vertical direction (see FIG. 3). As illustrated in FIG. 1, in a first embodiment, the rail 6 is fixed on an outer side part of the substrate processing apparatus 1. A number of a rail(s) 6 that is/are fixed on the substrate processing apparatus 1 may be, for example, four.

As illustrated in FIG. 1, in a first embodiment, four rails 6 are respectively arranged at a position that is adjacent to a first area 141, a position that is adjacent to a second area 142, a position that is adjacent to a third area 151, and a position that is adjacent to a fourth area 152. Additionally, a number and a position(s) of a rail(s) 6 that is/are fixed on an outer side part of the substrate processing apparatus 1 are not particularly limited.

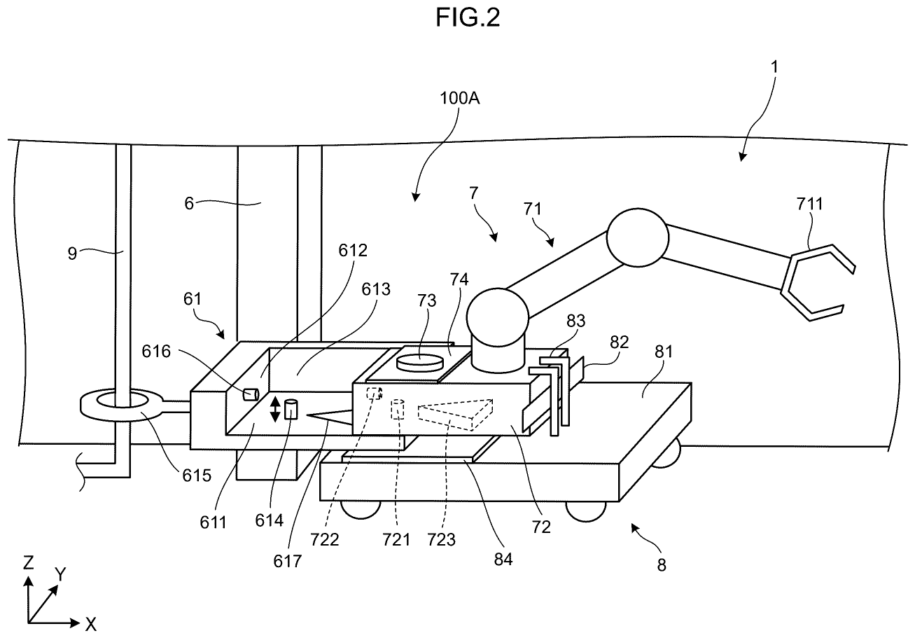

The working robot 7 is capable of being attached to or detached from the rail 6. Then, the working robot 7 that is attached to the rail 6 is capable of being lifted or lowered along the rail 6. Furthermore, the working robot 7 has an arm 71 that is capable of going to an inside of a processing unit. The working robot 7 is lifted or lowered along the rail 6 so as to move to a height of a processing unit as a maintenance target, and executes maintenance of such a processing unit by using the arm 71. Additionally, a detailed configuration of the working robot 7 will be described later with reference to FIG. 2.

The carriage 8 is a self-propelled carriage. Ion a first embodiment, the carriage 8 transfers the working robot 7 to the rail 6. Alternatively, the carriage 8 transfers the working robot 7 that is detached from the rail 6 to a predetermined waiting place.

The carriage 8 according to a first embodiment may have a transfer/placement mechanism for transferring and placing the working robot 7 to/on a base part 61 of the rail 6 as described later. The carriage 8 is capable of attaching or detaching the working robot 7 to/from the rail 6 by using such a transfer/placement mechanism. Additionally, a detailed configuration of the carriage 8 will be described later with reference to FIG. 2.

Next, a configuration of a maintenance system 100A according to a first embodiment will be explained in detail with reference to FIG. 2. FIG. 2 is a perspective view that illustrates an example of a configuration of a maintenance system 100A according to a first embodiment. A maintenance system 100A has a rail 6, a working robot 7, and a carriage 8, as described above.

As illustrated in FIG. 2, the rail 6 may have a base part 61 (an example of a second base part) that is capable of being lifted or lowered along such a rail 6. A base part 72 of the working robot 7 as described later is attached to the base part 61. The base part 61 is lifted or lowered along the rail 6, so that it is possible to lift or lower the working robot 7 in a vertical direction.

The base part 61 according to a first embodiment may have a placement surface 611, a first wall surface 612, and a second wall surface 613. Furthermore, the base part 61 according to a first embodiment may have a movable fixation pin 614, a power-receiving ring 615, a first terminal 616, and a guide groove 617.

The placement surface 611 is a surface where the base part 72 of the working robot 7 as described later is placed. The first wall surface 612 is a surface that is orthogonal to an outer wall of a substrate processing apparatus 1 and extends from the placement surface 611 in a direction of a Z-axis. In an example as illustrated in FIG. 2, the first wall surface 612 contacts a side surface of the base part 72 as described later on a side of a negative direction of an X-axis.

The second wall surface 613 is a surface that is parallel to an outer wall of the substrate processing apparatus 1, and extends from the placement surface 611 in a direction of a Z-axis. In an example as illustrated in FIG. 2, the second wall surface 613 contacts a side surface of the base part 72 as described later on a side of a positive direction of Y-axis.

The base part 61 may have the movable fixation pin 614. The fixation pin 614 may be located on the placement surface 611. The fixation pin 614 is capable of being lifted or lowered, for example, under control that is executed by a controller 201, and protrudes from the placement surface 611 as needed.

Furthermore, the base part 61 may have the power-receiving ring 615. The power-receiving ring 615 may be provided on a side surface of the base part 61 on a side of a negative direction of an X-axis. A power-supplying line 9 as described later is inserted through the power-receiving ring 615. The power-receiving ring 615 is capable of receiving a power from the power-supplying line 9.

Furthermore, the base part 61 may have the first terminal 616 that is electrically connected to the power-receiving ring 615. The first terminal 616 is connected to a second terminal 722 of the working robot 7 as described later. The first terminal 616 may be located on, for example, the first wall surface 612. According to such a configuration, it is possible to supply a power from the power-receiving ring 615 to the working robot 7 through the first terminal 616.

Furthermore, the base part 61 may have the guide groove 617 on the placement surface 611. As illustrated in FIG. 2, a shape of the guide groove 617 in a plan view may be, for example, a triangular shape that is sharp on a side of a negative direction of an X-axis. Such a guide groove 617 may be formed by cutting out, from the base part 61, a triangular shape that is provided from an end part of the placement surface 611 on a side of a positive direction of an X-axis to a central part of the placement surface 611.

Additionally, a number of a base part(s) 61 that is/are possessed by the rail 6 may be a plural number. According to such a configuration, it is possible to attach a plurality of working robots 7 to a single rail 6. Hence, it is possible to improve a working efficiency of the maintenance system 100A.

The power-supplying line 9 extends along the rail 6. The power-supplying line 9 may be electrically connected to the substrate processing apparatus 1. The power-supplying line 9 is inserted through the power-receiving ring 615 in a non-contact state thereof. According to such a configuration, it is possible to supply a power from the substrate processing apparatus 1 to the power-receiving ring 615 through the power-supplying line 9.

Specifically, the power-receiving ring 615 and the power-supplying line 9 function as a non-contact power-supplying mechanism. More specifically, it is possible to generate an induced electromotive force on the power-receiving ring 615 by an oscillating magnetic field that is formed around an axis of the power-supplying line 9. Thereby, it is possible to supply a power from the substrate processing apparatus 1 to the power-receiving ring 615 through the power-supplying line 9 in a non-contact manner.

According to such a configuration, it is possible to supply a power to the working robot 7 without connecting a power-supplying cable, etc., to the working robot 7. Hence, it is possible to reduce a risk that a power-supplying cable is drawn into a lifting or lowering working robot 7, etc.

Additionally, the power-supplying line 9 may be composed of, for example, a cable where an alternating current flows therethrough. Alternatively, the power-supplying line 9 may be composed of a conductor with a rod shape where an alternating current flows therethrough, etc.

The working robot 7 may have an arm 71, a base part 72 (an example of a first base part), a maintenance member 73, and a holding plate 74.

The arm 71 may be, for example, a multijoint arm. The arm 71 may have a gripping part 711 for gripping the maintenance member 73 on a distal end thereof. The arm 71 is provided on, for example, an upper part of the base part 72. The arm 71 is capable of moving the gripping part 711 in multiple directions while the base part 72 is provided as a fulcrum thereof.

The arm 71 goes to an inside of a processing unit and executes maintenance of such a processing unit. Specifically, the gripping part 711 is caused to go to an inside of a processing unit and maintenance of such a processing unit is executed by using the maintenance member 73 that is gripped by the gripping part 711.

The maintenance member 73 may be, for example, a cleaning member. In such a case, the working robot 7 is capable of executing cleaning of a processing unit by using a cleaning member. Alternatively, the maintenance member 73 may be, for example, a component that constitutes a processing unit. Thus, the working robot 7 is also capable of executing component replacement of a processing unit, etc. Additionally, the holding plate 74 for placing the maintenance member 73 thereon may be provided on an upper surface of the base part 72.

The base part 72 has, for example, a rectangular solid shape. As described above, the arm 71 may be provided on an upper part of the base part 72. The base part 72 is placed on the placement surface 611 of the base part 61. The base part 72 may have a pin hole 721, a second terminal 722, and a protrusion part 723. Additionally, a shape of the base part 72 is not particularly limited.

The pin hole 721 may be located in a bottom surface of the base part 72. The fixation pin 614 of the base part 61 is inserted into the pin hole 721. Thereby, it is possible to join the working robot 7 and the rail 6.

The second terminal 722 may be located on a side surface of the base part 72 on a side of a negative direction of an X-axis. The second terminal 722 is connected to the first terminal 616 of the base part 61. Thereby, it is possible to supply a power from the power-receiving ring 615 to the working robot 7 through the first terminal 616 and the second terminal 722.

Additionally, the first terminal 616, the second terminal 722, and the rail 6 may a communication function. According to such a configuration, it is possible to control an operation of the working robot 7 under control that is executed by the controller 201.

Additionally, the working robot 7 may execute a maintenance operation autonomously. In such a case, the working robot 7 may incorporate a computer for controlling an operation of the working robot 7 in, for example, an inside of the base part 72.

The protrusion part 723 is located on a bottom surface of the base part 72. The protrusion part 723 may have a triangular shape that is substantially identical to a shape of the guide groove 617 of the base part 61. As specifically described later, according to such a configuration, it is possible to readily attach the base part 72 to the base part 61 of the rail 6.

The carriage 8 transfers the working robot 7. The carriage 8 is capable of traveling autonomously. The carriage 8 according to a first embodiment may have a placement surface 81 for placing the working robot 7 thereon. Furthermore, the carriage 8 according to a first embodiment may have a pushing part 82 and a claw part 83 as a transfer/placement mechanism for transferring and placing the working robot 7 to/on the base part 61 pf the rail 6.

The pushing part 82 is provided, for example, so as to contact the base part 72 that is placed on the placement surface 81, from a horizontal direction. As illustrated in FIG. 2, the pushing part 82 may be, for example, a plate member that has a flat surface that is orthogonal to an X-axis. Such a plate member may be attached to the claw part 83 as described later. A transfer/placement mechanism pushes the working robot 7 by using the pushing part 82, so that it is possible to transfer and place the working robot 7 to/on the base part 61 of the rail 6. Additionally, a specific operation of a transfer/placement mechanism will be described later.

The claw part 83 is provided, for example, so as to contact the base part 72 that is placed on the placement surface 81, from an upper side in a vertical direction. Specifically, for example, the claw part 83 may protrude upward from the placement surface 81 in a vertical direction or may be provided in such a manner that a shape thereof in a side view in a direction of a Y-axis is an upside-down L-shape. A transfer/placement mechanism pulls the working robot 7 by using the claw part 83, so that it is possible to detach the working robot 7 from the base part 61 of the rail 6.

As illustrated in FIG. 2, a plate member 84 may be located between the placement surface 81 and the base part 72. The plate member 84 may be composed of a self-lubricating resin. For a self-lubricating resin, for example, Teflon (registered trademark), etc., are provided. As specifically described later, such a plate member 84 is provided on the carriage 8, so that it is possible to transfer and place the working robot 7 to/on the base part 61 of the rail 6 smoothly.

### Operation of Transfer/Placement Mechanism

Next, an operation of a transfer/placement mechanism as described above will be explained in more detail with reference to FIG. 2.

A transfer/placement mechanism pushes a base part 72 along a direction that is parallel to an outer wall of a substrate processing apparatus 1, by using a pushing part 82, so as to move a working robot 7 from a placement surface 81 of a carriage 8 to a placement surface 611 of a base part 61. For example, in an example as illustrated in FIG. 2, a transfer/placement mechanism moves the working robot 7 to a side of a negative direction of an X-axis.

Herein, a transfer/placement mechanism moves the working robot 7 so as to match a position of a pin hole 721 of a base part 72 and a fixation pin 614 of the base part 61. Then, after movement of the working robot 7 is completed, the fixation pin 614 is lifted from the placement surface 611 and is inserted into the pin hole 721. Thereby, the working robot 7 and a rail 6 are joined.

As described above, the base part 61 may have a guide groove 617. Furthermore, as described above, the base part 72 may have a protrusion part 723. According to such a configuration, for example, in an example as illustrated in FIG. 2, even in a case where carrying-in is executed in a state where the base part 72 is shifted with respect to the base part 61 in a direction of a Y-axis, it is possible to align both of them appropriately.

Specifically, while the protrusion part 723 is guided by the guide groove 617, the base part 72 is transferred to and placed on the base part 61, so that it is possible to adjust a position of the base part 72 with respect to the base part 61 appropriately while both of them are connected. Hence, according to such a configuration, it is possible to relax an accuracy of a position of carrying-in of the working robot 7 that is executed by the carriage 8.

A transfer/placement mechanism pulls the base part 72 along a direction that is parallel to an outer wall of the substrate processing apparatus 1, by using a claw part 83, so as to move the working robot 7 from the placement surface 611 to the placement surface 81. For example, in an example as illustrated in FIG. 2, a transfer/placement mechanism moves the working robot 7 to a side of a positive direction of an X-axis.

Thus, according to the carriage 8 that has the pushing part 82 and the claw part 83 as a transfer/placement mechanism, it is possible to attach or detach the working robot 7 to/from the base part 61 of the rail 6 by utilizing a driving force of the carriage 8. Hence, it is possible to facilitate a mechanism for attaching or detaching the working robot 7 to/from the rail 6.

Furthermore, as described above, when the working robot 7 is attached to or detached from the base part 61, the working robot 7 is moved along a direction that is parallel to an outer wall of the substrate processing apparatus 1, so that it is possible to reduce applying of a pushing force and/or a pulling force to the substrate processing apparatus 1. Thereby, it is possible to reduce a risk that an adverse effect is caused in the substrate processing apparatus 1.

As described above, a plate member 84 that is composed of a self-lubricating resin may be located between the base part 72 and the placement surface 81. According to such a configuration, when the working robot 7 is transferred to and placed on the base part 61, it is possible to reduce a friction that is cased between the base part 61 and the base part 72. Hence, it is possible to transfer and place the working robot 7 to/on the base part 61 smoothly.

### Operation at Time of Maintenance

Next, an operation of a maintenance system 100A at a time when maintenance of a substrate processing apparatus 1 is executed will be explained with reference to FIG. 3. FIG. 3 is a side view that illustrates a situation of maintenance that is executed by a maintenance system 100A according to a first embodiment. Additionally, FIG. 3 illustrates an example of a case where a working robot 7 executes maintenance of a processing unit that is located in a third area 151 of a second processing block 15.

In maintenance of a processing unit, first, a working robot 7 is lifted or lowered along a rail 6 so as to move to a predetermined working position. A predetermined working position as mentioned herein may be, specifically, a position that faces a processing unit in a third area 151 that is a maintenance target. Then, the working robot 7 that is arranged at a working position causes a gripping part 711 of an arm 71 to go to an inside of a processing unit, so as to execute maintenance of such a processing unit by using a maintenance member 73.

Additionally, an opening or closing port where the arm 71 goes to an inside therethrough may be provided on a side surface of a substrate processing apparatus 1 and a side surface of a processing unit, although illustration thereof is omitted in FIG. 3. Opening or closing of such an opening or closing port may be controlled by, for example, a controller 201.

Additionally, maintenance of processing units that are located in a first area 141, a second area 142, and a fourth area 152 may be executed by the working robot 7 that is attached to the rail 6 that is located so as to be adjacent to each of the first area 141, the second area 142, and the fourth area 152. Additionally, the working robot 7 is transferred to each rail 6 by a carriage 8.

In the maintenance system 100A according to a first embodiment, the working robot 7 is attached to the rail 6 that is fixed on the substrate processing apparatus 1, so that it is possible to integrate the working robot 7 and the substrate processing apparatus 1. Thereby, it is possible to reduce a problem such as wobbling of the working robot 7.

For example, in a case where a working robot that executes maintenance, per se, has a lifting/lowering mechanism, a position of a center of gravity of such a working robot is high when such maintenance is executed at a comparatively high position in a vertical direction, so that such a working robot is readily wobbled. If a working robot is wobbled, a working accuracy of such a working robot may be degraded.

On the other hand, in a case where the working robot 7 and the substrate processing apparatus 1 are integrated, a weight of the substrate processing apparatus 1 is comparatively large, so that a center of gravity of the working robot 7 and the substrate processing apparatus 1 that are integrated is stabilized. Hence, in the maintenance system 100A according to a first embodiment, it is possible to reduce wobbling of the working robot 7, and thereby, it is possible to improve an accuracy of maintenance of a processing unit that is executed by the working robot 7.

### Second Embodiment

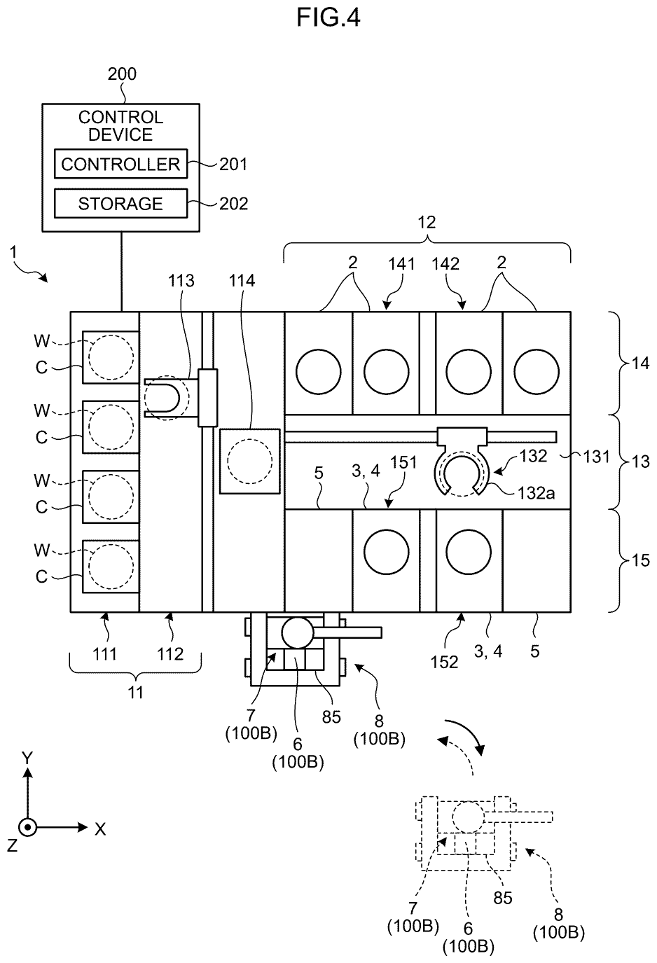

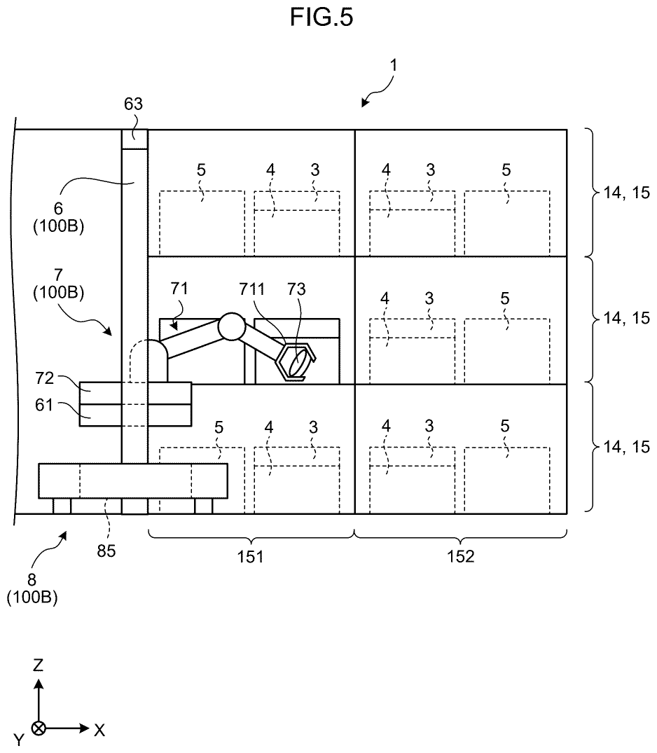

Next, a configuration of a maintenance system 100B according to a second embodiment will be explained with reference to FIG. 4 and FIG. 5. FIG. 4 is a plan view that illustrates an example of a configuration of a substrate processing apparatus 1 and a maintenance system 100B according to a second embodiment. FIG. 5 is a side view that illustrates a situation of maintenance that is executed by a maintenance system 100B according to a second embodiment.

As described above, an example of a case where a rail 6 is fixed on an outer side part of a substrate processing apparatus 1 has been explained in a first embodiment. On the other hand, as illustrated in FIG. 4, in a second embodiment, a rail 6 may be capable of being attached to or detached from a substrate processing apparatus 1.

A maintenance system 100B according to a second embodiment has a rail 6, a working robot 7 that is attached to the rail 6, and a carriage 8. In a second embodiment, the carriage 8 transfers the rail 6 with the working robot 7 that is attached thereto to an outer side part of a substrate processing apparatus 1. Additionally, in a second embodiment, the rail 6 may be fixed to the carriage 8.

As illustrated in FIG. 5, on an upper part of the rail 6 according to a second embodiment, a fixation part 63 for fixing such a rail 6 to the substrate processing apparatus 1 may be provided. The fixation part 63 may be, for example, a movable hook, etc. The fixation part 63 may be coupled to, for example, a non-illustrated frame that is provided on an outer wall of the substrate processing apparatus 1, etc. According to such a configuration, it is possible to readily fix the rail 6 that is transferred by the carriage 8 to the substrate processing apparatus 1.

As illustrated in FIG. 4, in a second embodiment, the rail 6 may be arranged at a position that is adjacent to a first area 141, a second area 142, a third area 151, or a fourth area 152. For example, in FIG. 4, the rail 6 is arranged at a position that is adjacent to the third area 151. Additionally, a position of the rail 6 that is attached to the substrate processing apparatus 1 is not particularly limited.

As illustrated in FIG. 4, the carriage 8 according to a second embodiment may have a recessed part 85 that is dented from an outer side surface of the carriage 8 toward an inside thereof in a plan view in a vertical direction and penetrates through the carriage 8 in a vertical direction. Then, the rail 6 and the working robot 7 may be located in an inside of the recessed part 85 in a plan view in a vertical direction.

According to such a configuration, it is possible to lower the working robot 7 along the rail 6 more downward, as compared with a case where the carriage 8 does not have the recessed part 85. Thereby, the working robot 7 is capable of executing maintenance appropriately, even for a processing unit that is located at a lower part of the substrate processing apparatus 1.

In the maintenance system 100B according to a second embodiment, the rail 6 with the working robot 7 that is attached thereto is fixed to the substrate processing apparatus 1, so that it is possible to integrate the working robot 7 and the substrate processing apparatus 1. Hence, similarly to a maintenance system 100A according to a first embodiment, it is possible to reduce wobbling of the working robot 7, and thereby, it is possible to improve an accuracy of maintenance of a processing unit that is executed by the working robot 7.

### Third Embodiment

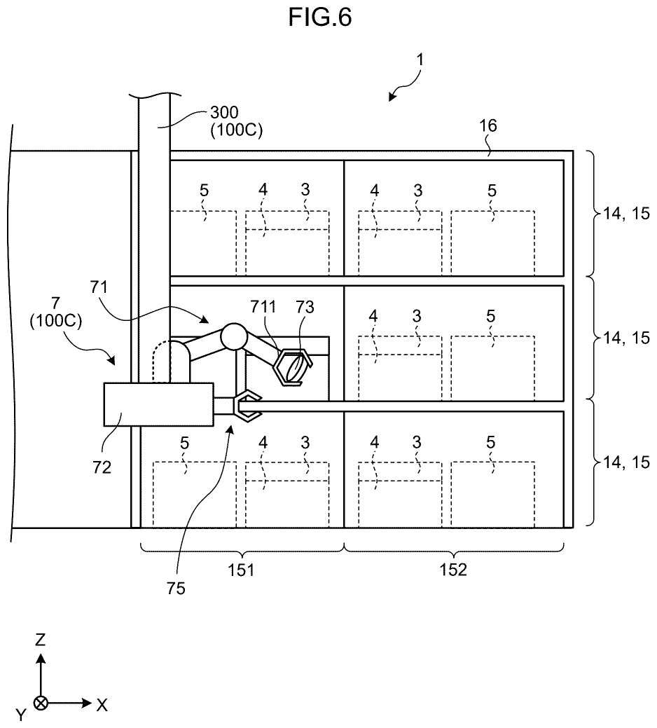

Next, a substrate processing apparatus 1 and a maintenance system 100C according to a third embodiment will be explained with reference to FIG. 6. FIG. 6 is a side view that illustrates a situation of maintenance that is executed by a maintenance system 100C according to a third embodiment.

As illustrated in FIG. 6, a substrate processing apparatus 1 according to a third embodiment may include a frame 16. As illustrated in FIG. 6, the frame 16 may be provided on an outer wall surface of a substrate processing apparatus 1 along edges of a first processing block 14 and a second processing block 15.

As illustrated in FIG. 6, the maintenance system 100C according to a third embodiment may include a lifting/lowering mechanism 300 for lifting or lowering a working robot 7 along a vertical direction, instead of a rail 6. Furthermore, the working robot 7 according to a third embodiment may have a gripping mechanism 75 for gripping the frame 16 of the substrate processing apparatus 1.

The lifting/lowering mechanism 300 lifts or lowers the working robot 7 along a vertical direction, so that it is possible to arrange the working robot 7 at a predetermined working position. Additionally, the lifting/lowering mechanism 300 may be, for example, a crane that is attached and provided to the substrate processing apparatus 1, etc.

The gripping mechanism 75 may be provided on a base part 72 of the working robot 7. The gripping mechanism 75 grips the frame 16 when the working robot 7 is arranged at a predetermined working position.

In the maintenance system 100C according to a third embodiment, the frame 16 is gripped by the gripping mechanism 75, so that it is possible to fix the working robot 7 to the substrate processing apparatus 1. Hence, similarly to a maintenance system 100A, 100B as described above, it is possible to reduce wobbling of the working robot 7, and thereby, it is possible to improve an accuracy of maintenance of a processing unit that is executed by the working robot 7.

### Fourth Embodiment

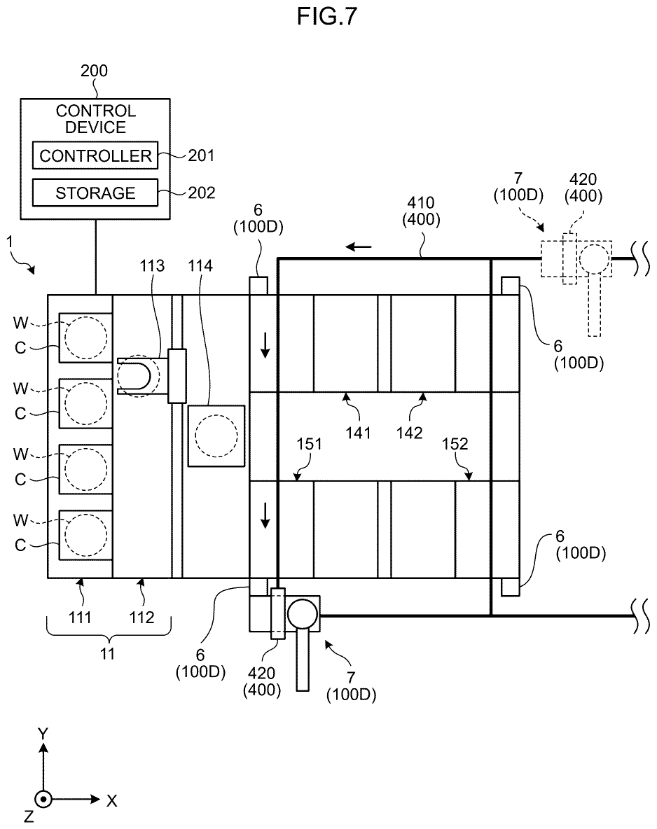

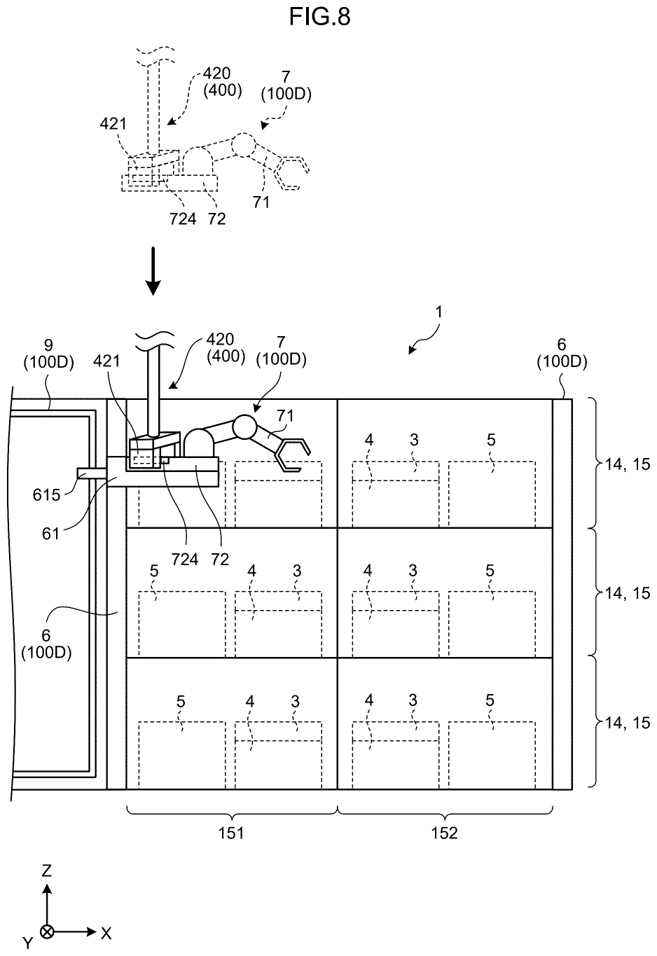

Next, a maintenance system 100D according to a fourth embodiment will be explained with reference to FIG. 7 and FIG. 8. FIG. 7 is a plan view for explaining an operation of a maintenance system 100D according to a fourth embodiment. FIG. 8 is a side view for explaining an operation of a maintenance system 100D according to a fourth embodiment.

An example of a case where a working robot 7 is transferred to a rail 6 that is fixed on an outer side part of a substrate processing apparatus 1 by using a carriage 8 has been explained in a first embodiment as described above. On the other hand, as illustrated in FIG. 7, in a fourth embodiment, a working robot 7 may be transferred to a rail 6 by using a ceiling transfer mechanism 400 (an example of a transfer device) that is provided separately from a substrate processing apparatus 1, instead of a carriage 8.

As illustrated in FIG. 7, a ceiling transfer mechanism 400 may have, for example, a rail 410 that is provided on a ceiling on an upper side of a substrate processing apparatus 1, and a crane 420 that is capable of being moved along the rail 410.

As illustrated in FIG. 7, the rail 410 may be arranged, for example, in a grid-like manner, in a case where a plan view of the ceiling transfer mechanism 400 in a vertical direction is provided. In FIG. 7, the rail 410 is schematically indicated by a black line. The ceiling transfer mechanism 400 moves, in a state where a working robot 7 is held by the crane 420, such a crane 420 along the rail 410, so that it is possible to move the working robot 7 in a horizontal direction (a direction that is parallel to an XY-plane). Additionally, arrangement of the rail 410 is not limited to an example as illustrated in FIG. 7.

As illustrated in FIG. 8, the crane 420 may have an arm 421 that is capable of being lifted or lowered along a vertical direction. The crane 420 lifts or lowers, in a state where the working robot 7 is gripped by the arm 421, such an arm 421 in a vertical direction (a direction of a Z-axis), so that it is possible to move the working robot 7 in a vertical direction.

As illustrated in FIG. 8, the working robot 7 according to a fourth embodiment may heave a protrusion part 724 that is gripped by the arm 421 of the crane 420. The protrusion part 724 is provided so as to protrude from, for example, a side surface of a base part 72. For example, in an example as illustrated in FIG. 8, the base part 72 has the protrusion part 724 on a side surface on a side of a positive direction of a Y-axis and a side surface on a side of a negative direction of such a Y-axis.

Thus, the working robot 7 is provided with the protrusion part 724, so that it is possible to transfer the working robot 7 by using a transfer device such as the ceiling transfer mechanism 400.

In a fourth embodiment, the ceiling transfer mechanism 400 transfers the working robot 7 to the substrate processing apparatus 1, for example, as mentioned below. First, the crane 420 holds (grips) the working robot 7 at a (non-illustrated) predetermined waiting position. Then, the crane 420 is moved horizontally along the rail 410 and is arranged above the rail 6 (see FIG. 7). Then, the crane 420 lowers the arm 421 so as to place the working robot 7 on a base part 61 of the rail 6 (see FIG. 8). Subsequently, a fixation pin 614 of the base part 61 is inserted into a pin hole 721 of the base part 72, so that the working robot 7 is attached to the rail 6.

In the maintenance system 100D according to a fourth embodiment, the working robot 7 is attached to the rail 6 that is fixed on the substrate processing apparatus 1, so that it is possible to integrate the working robot 7 and the substrate processing apparatus 1. Hence, similarly to a maintenance system 100A according to a first embodiment, it is possible to reduce wobbling of the working robot 7, and thereby, it is possible to improve an accuracy of maintenance of a processing unit that is executed by the working robot 7.

Additionally, the rail 6 according to a fourth embodiment may be capable of being attached to or detached from the substrate processing apparatus 1. That is, the rail 6 according to a fourth embodiment may have a fixation part 63 as described above on an upper part of such a rail 6. In such a case, the rail 6 may be transferred to the substrate processing apparatus 1 by a carriage 8. Thus, the maintenance system 100D according to a fourth embodiment may be configured in such a manner that the rail 6 is transferred by the carriage 8 and the working robot 7 is transferred by the ceiling transfer mechanism 400.

### Fifth Embodiment

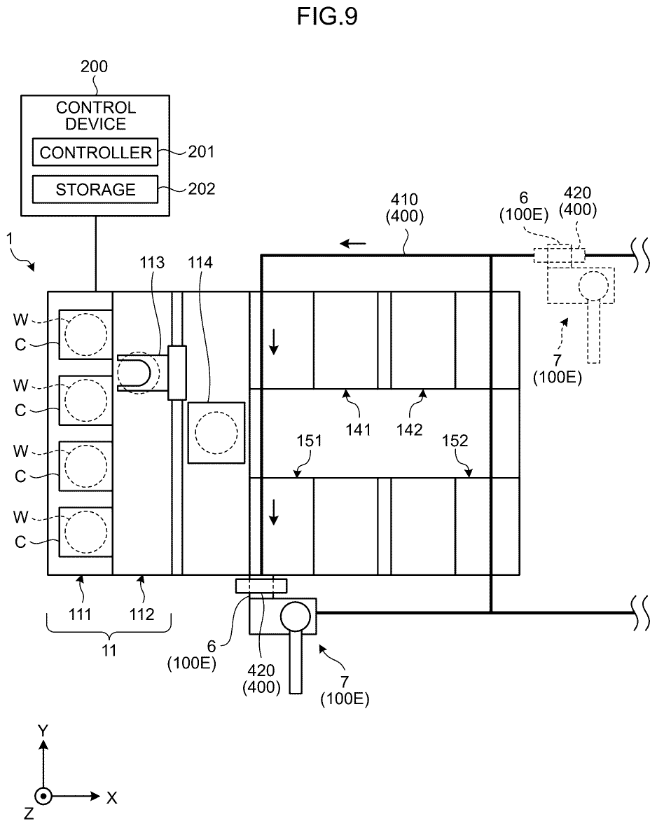

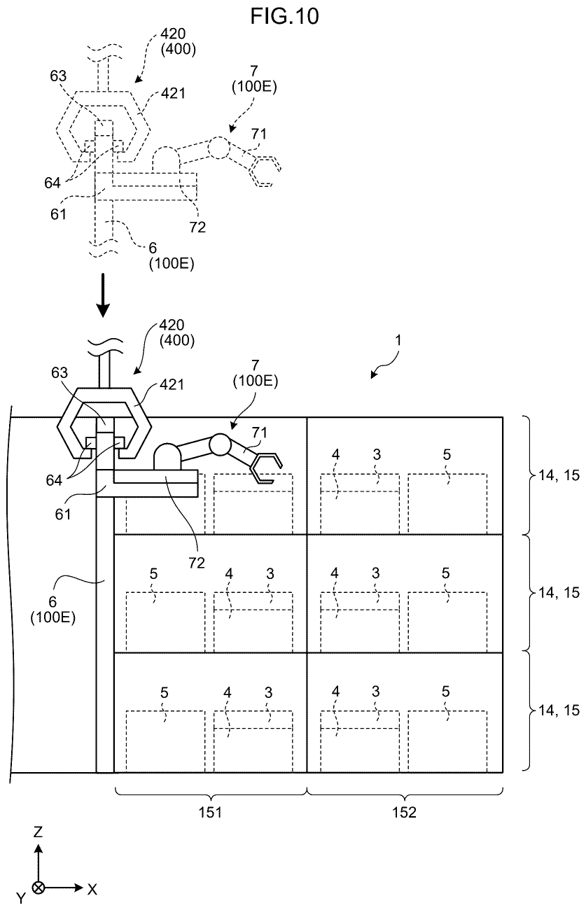

Next, a maintenance system 100E according to a fifth embodiment will be explained with reference to FIG. 9 and FIG. 10. FIG. 9 is a plan view for explaining an operation of a maintenance system 100E according to a fifth embodiment. FIG. 10 is a side view for explaining an operation of a maintenance system 100E according to a fifth embodiment.

An example of a case where a rail 6 with a working robot 7 that is attached thereto is transferred to an outer side part of a substrate processing apparatus 1 by using a carriage 8 has been explained in a second embodiment as described above. On the other hand, as illustrated in FIG. 9, in a fifth embodiment, a rail 6 with a working robot 7 that is attached thereto may be transferred to an outer side part of a substrate processing apparatus 1 by using a ceiling transfer mechanism 400 as described above, instead of a carriage 8.

As illustrated in FIG. 9, a ceiling transfer mechanism 400 moves, in a state where a rail 6 is held by a crane 420, such a crane 420 along a rail 410, so that it is possible to move the rail 6 in a horizontal direction (a direction that is parallel to an XY-plane). Furthermore, the crane 420 lifts or lowers, in a state where the rail 6 is gripped by an arm 421, such an arm 421 in vertical direction (a direction of a Z-axis), so that it is possible to move the rail 6 in a vertical direction.

As illustrated in FIG. 10, the rail 6 according to a fifth embodiment may have a fixation part 63 as described above on an upper part of such a rail 6. Furthermore, the rail 6 according to a fifth embodiment may have a protrusion part 64 that is gripped by the arm 421 of the crane 420. The protrusion part 64 may be provided so as to protrude from, for example, a side part of the rail 6 on an upper part of the rail 6.

Thus, the rail 6 is provided with the protrusion part 64, so that it is possible to transfer a working robot 7 by using a transfer device such as the ceiling transfer mechanism 400.

In a fifth embodiment, the ceiling transfer mechanism 400 transfers the rail 6 to an outer side part of a substrate processing apparatus 1, for example, as mentioned below. First, the crane 420 holds (grips) the rail 6 at a (non-illustrated) predetermined waiting position. Then, the crane 420 is moved horizontally along the rail 410 and is arranged at a predetermined position (see FIG. 9). A predetermined position as mentioned herein may be, for example, a position that is adjacent to a third area 151 in a plan view of the substrate processing apparatus 1, as illustrated in FIG. 9. Then, the crane 420 lowers the arm 421 so as to arrange the rail 6 at a height that is identical to that of the substrate processing apparatus 1. Subsequently, the rail 6 is fixed on the substrate processing apparatus 1 by the fixation part 63.

In the maintenance system 100E according to a fifth embodiment, the rail 6 with the working robot 7 that is attached thereto is fixed to the substrate processing apparatus 1, so that it is possible to integrate the working robot 7 and the substrate processing apparatus 1. Hence, similarly to a maintenance system 100B according to a second embodiment, it is possible to reduce wobbling of the working robot 7, and thereby, it is possible to improve an accuracy of maintenance of a processing unit that is executed by the working robot 7.

Additionally, although the rail 6 has a length that is comparable with a height of the substrate processing apparatus 1 in an example as illustrated in FIG. 10, a length of the rail 6 may be, for example, comparable with heights of a first processing block 14 and a second processing block 15. Thus, the rail 6 with a comparatively small length is used, so that it is possible to improve an efficiency of transfer of the rail 6 that is executed by the ceiling transfer mechanism 400.

Although the present disclosure has been explained above in detail, the present disclosure is not limited to an embodiment(s) as described above and a variety of modifications, improvements, etc., are allowed without departing from an essence of the present disclosure.

Additionally, each embodiment as described above has been explained by providing, as an example, a configuration that has a plurality of processing blocks where substrate processing apparatuses 1 are laminated in multiple stages, in other words, a configuration that has a plurality of processing units that are laminated in multiple stages. However, such a substrate processing apparatus 1 does not have to be a configuration that has a plurality of laminated processing blocks (processing modules). For example, the substrate processing apparatus 1 may be a configuration that has a processing module with a large dimension in a vertical direction in a single stage configuration (in other words, a flat pile). Furthermore, the substrate processing apparatus 1 may be a configuration where a processing module is laminated on a component other than a processing module, for example, a component of an exhaust system or a power supply system, etc. That is, the substrate processing apparatus 1 may be a configuration where an exhaust system or a power supply system is arranged in a block at a lower stage and a processing unit is arranged in a block at an upper stage.

It should be considered that an embodiment(s) as disclosed herein is/are not limitative but is/are illustrative in all aspects thereof. In fact, it is possible to implement an embodiment(s) as described above in a variety of modes. Furthermore, an embodiment(s) as described above may be omitted, substituted, or modified in various modes, without departing from an appended claim(s) and an essence thereof.

An embodiment provides a maintenance system and a maintenance method that are suitable for maintenance in a vertical direction.

A maintenance system according to an aspect of an embodiment has a rail, a working robot, and a self-propelled carriage. The rail is fixed on an outer side part of a substrate processing apparatus that has a processing unit, and extends in a vertical direction. The working robot is capable of being attached to or detached from the rail and is capable of being lifted or lowered along the rail. The self-propelled carriage transfers the working robot. The working robot has an arm that is capable of going to an inside of the processing unit.

According to an embodiment, it is possible to provide a maintenance system and a maintenance method that are suitable for maintenance in a vertical direction.

Additionally, it is possible for the present technique to provide a configuration(s) as provided below.
(1) A maintenance system that executes maintenance of a substrate processing apparatus that has a processing unit, wherein
the maintenance system has:
a rail that is fixed on an outer side part of the substrate processing apparatus and that extends in a vertical direction;
a working robot that is capable of being attached to or detached from the rail and that is capable of being lifted or lowered along the rail; and
a self-propelled carriage that transfers the working robot, wherein
the working robot has an arm that is capable of going to an inside of the processing unit.
(2) The maintenance system according to (1) as described previously, wherein
the working robot has a first base part that has a pin hole,
the rail has a second base part that is capable of being lifted or lowered along the rail and that has a movable fixation pin that is inserted into the pin hole, and
the fixation pin of the second base part is inserted into the pin hole of the first base part so as to join the working robot and the rail.
(3) The maintenance system according to (2) as described previously, wherein
the carriage has a transfer/placement mechanism that transfers and places the working robot to/on the second base part, and
the transfer/placement mechanism moves the working robot so as to match a position of the pin hole and a position of the fixation pin.
(4) The maintenance system according to (3) as described previously, wherein
the transfer/placement mechanism has a pushing part that is provided so as to contact the first base part of the working robot from a horizontal direction, and a claw part that contacts the first base part from an upper side in a vertical direction,
the working robot is moved from the carriage onto the second base part by using the pushing part, and
the working robot is moved from the second base part to the carriage by using the claw part.
(5) The maintenance system according to (4) as described previously, wherein
the transfer/placement mechanism moves the working robot along a direction that is parallel to an outer wall of the substrate processing apparatus by using the pushing part or the claw part.
(6) The maintenance system according to any one of (2) to (5) as described previously, having:
a power-receiving ring that is provided on the second base part;
a power-supplying line that extends along the rail and that is inserted through the power-receiving ring in a non-contact state thereof;
a first terminal that is provided on the second base part and that is electrically connected to the power-receiving ring; and
a second terminal that is provided on the first base part and that is electrically connected to the first terminal.
(7) The maintenance system according to any one of (2) to (6) as described previously, wherein
the rail has a plurality of the second base parts.
(8) A maintenance method that is executed by a maintenance system that includes:
a rail that is fixed on an outer side part of a substrate processing apparatus that has a processing unit, and that extends in a vertical direction;
a working robot that is capable of being attached to or detached from the rail and that has an arm that is capable of going to an inside of the processing unit; and
a self-propelled carriage, wherein
the maintenance method includes:
a step of transferring the working robot to the rail by using the carriage;
a step of lifting or lowering the working robot to a predetermined working position along the rail; and
a step of executing maintenance of the processing unit at the working position by using the arm.
(9) A maintenance system that executes maintenance of a substrate processing apparatus that has a processing unit, wherein
the maintenance system has:
a rail that is capable of being attached to or detached from the substrate processing apparatus and that extends in a vertical direction;
a working robot that is attached to the rail and that is capable of being lifted or lowered along the rail; and
a self-propelled carriage that transfers the rail, wherein
the working robot has an arm that is capable of going to an inside of the processing unit.
(10) The maintenance system according to (9) as described previously, wherein
a fixing part for fixing the rail to the substrate processing apparatus is provided on an upper part of the rail.
(11) The maintenance system according to (9) or (10) as described previously, wherein
the carriage has a recessed part that is dented from an outer side surface to an inside thereof in a plan view in a vertical direction and that penetrates through the carriage in a vertical direction,
the working robot has a base part that is a member with the arm that is attached thereto, and that is lifted or lowered along the rail, and
the rail and the base part are located in an inside of the recessed part in the plan view in a vertical direction.
(12) The maintenance system according to (11) as described previously, wherein
the rail has a plurality of the base parts.
(13) A maintenance method that is executed by a maintenance system that includes:
a rail that is capable of being attached to or detached from a substrate processing apparatus that has a processing unit, and that extends in a vertical direction;
a working robot that is attached to the rail and that has an arm that is capable of going to an inside of the processing unit; and
a self-propelled carriage, wherein
the maintenance method includes:
a step of transferring the rail to the substrate processing apparatus by using the carriage;
a step of lifting or lowering the working robot to a predetermined working position along the rail, and
a step of executing maintenance of the processing unit at the working position by using the arm.
(14) A maintenance system that executes maintenance of a substrate processing apparatus that has a processing unit, wherein
the maintenance system has:
a working robot that has an arm that is capable of going to an inside of the processing unit and a gripping mechanism that grips a frame of the substrate processing apparatus; and
a lifting/lowering mechanism that lifts or lowers the working robot in a vertical direction.
(15) A maintenance method that is executed by a maintenance system that includes:
a working robot that has an arm that is capable of going to an inside of a processing unit in a substrate processing apparatus and a gripping mechanism that grips a frame of the substrate processing apparatus, and
a lifting/lowering mechanism that lifts or lowers the working robot in a vertical direction, wherein
the maintenance method includes:
a step of lifting or lowering the working robot to a predetermined working position by the lifting/lowering mechanism; and
a step of executing maintenance of the processing unit at the working position by using the arm in a state where the frame is gripped by the gripping mechanism.
(16) A maintenance system that executes maintenance of a substrate processing apparatus that has a processing unit, wherein
the maintenance system has:
a rail that is fixed on an outer side part of the substrate processing apparatus and that extends in a vertical direction; and
a working robot that is capable of being attached to or detached from the rail and is capable of being lifted or lowered along the rail, and that has an arm that is capable of going to an inside of the processing unit, wherein
the working robot is configured to be capable of being transferred by a transfer device.
(17) The maintenance system according to (16) as described previously, wherein
the working robot has a protrusion part that is gripped by an arm that is included in the transfer device.
(18) A maintenance method that is executed by a maintenance system that includes:
a rail that is fixed on an outer side part of a substrate processing apparatus that has a processing unit, and that extends in a vertical direction; and
a working robot that is capable of being attached to or detached from the rail and is capable of being lifted or lowered along the rail, that has an arm that is capable of going to an inside of the processing unit, and that is configured to be capable of being transferred by a transfer device, wherein
the maintenance method includes:
a step of transferring the working robot to the rail by the transfer device;
a step of lifting or lowering the working robot to a predetermined working position along the rail; and
a step of executing maintenance of the processing unit at the working position by using the arm.
(19) A maintenance system that executes maintenance of a substrate processing apparatus that has a processing unit, wherein
the maintenance system has:
a rail that is capable of being attached to or detached from the substrate processing apparatus and that extends in a vertical direction; and
a working robot that is attached to the rail, that is capable of being lifted or lowered along the rail, and that has an arm that is capable of going to an inside of the processing unit, wherein
the rail is configured to be capable of being transferred by a transfer device.
(20) The maintenance system according to (19) as described previously, wherein
the rail has a protrusion part that is gripped by an arm that is included in the transfer device.
(21) A maintenance method that is executed by a maintenance system that includes:
a rail that is capable of being attached to or detached from a substrate processing apparatus that has a processing unit, that extends in a vertical direction, and that is configured to be capable of being transferred by a transfer device; and
a working robot that is attached to the rail, that is capable of being lifted or lowered along the rail, and that has an arm that is capable of going to an inside of the processing unit, wherein
the maintenance method includes:
a step of transferring the rail to the substrate processing apparatus by the transfer device;
a step of lifting or lowering the working robot to a predetermined working position along the rail; and
a step of executing maintenance of the processing unit at the working position by using the arm.

What is claimed is:

1. A maintenance system, comprising:
a rail that is fixed on an outer side part of a substrate processing apparatus that includes a processing unit, and that extends in a vertical direction;
a working robot that is capable of being attached to or detached from the rail and that is capable of being lifted or lowered along the rail; and
a self-propelled carriage that transfers the working robot, wherein
the working robot includes an arm that is capable of going to an inside of the processing unit.

2. The maintenance system according to claim 1, wherein
the working robot includes a first base part that includes a pin hole, and
the rail includes a second base part that is capable of being lifted or lowered along the rail and that includes a movable fixation pin that is inserted into the pin hole.

3. The maintenance system according to claim 2, wherein
the carriage includes a transfer/placement mechanism that transfers and places the working robot to/on the second base part.

4. The maintenance system according to claim 3, wherein
the transfer/placement mechanism includes a pushing part that is provided to contact the first base part of the working robot from a horizontal direction, and a claw part that contacts the first base part from an upper side in a vertical direction.

5. The maintenance system according to claim 2, further comprising:
a power-receiving ring that is provided on the second base part;
a power-supplying line that extends along the rail and that is inserted through the power-receiving ring in a non-contact state thereof;
a first terminal that is provided on the second base part and that is electrically connected to the power-receiving ring; and
a second terminal that is provided on the first base part and that is electrically connected to the first terminal.

6. The maintenance system according to claim 2, wherein
the second base part includes a plurality of second base parts.

7. A maintenance system, comprising:
a rail that is capable of being attached to or detached from a substrate processing apparatus that includes a processing unit, and that extends in a vertical direction;
a working robot that is attached to the rail and that is capable of being lifted or lowered along the rail; and
a self-propelled carriage that transfers the rail, wherein
the working robot includes an arm that is capable of going to an inside of the processing unit.

8. The maintenance system according to claim 7, further comprising
a fixing part that fixes the rail to the substrate processing apparatus and that is provided on an upper part of the rail.

9. The maintenance system according to claim 7, wherein
the carriage includes a recessed part that is dented from an outer side surface to an inside thereof in a plan view in a vertical direction and that penetrates through the carriage in a vertical direction,
the working robot includes a base part that is provided with the arm that is attached thereto, and that is lifted or lowered along the rail, and
the rail and the base part are located in the recessed part in the plan view in a vertical direction.

10. The maintenance system according to claim 9, wherein
the base part includes a plurality of base parts.

11. A maintenance system, comprising:
a working robot that includes an arm that is capable of going to an inside of a processing unit that is included in a substrate processing apparatus, and a gripping mechanism that grips a frame of the substrate processing apparatus; and
a lifting/lowering mechanism that lifts or lowers the working robot in a vertical direction.
